(19) United States
(12) Patent Application Publication
(10) Pub. No.: US 2025/0378873 A1
(43) Pub. Date: Dec. 11, 2025

(54) APPARATUSES AND METHODS FOR PROVIDING MEMORY DEVICE BLEEDER FUNCTIONALITY

(71) Applicant: Micron Technology, Inc., Boise, ID (US)

(72) Inventor: Daniele Vimercati, El Dorado Hills, CA (US)

(21) Appl. No.: 19/226,453

(22) Filed: Jun. 3, 2025

Related U.S. Application Data
(60) Provisional application No. 63/657,220, filed on Jun. 7, 2024.

(51) Int. Cl. G11C 11/4093; G11C 11/4096; G11C 11/4099

(52) U.S. Cl. CPC G11C 11/4093; G11C 11/4096; G11C 11/4099

(57) ABSTRACT

Systems, methods, and apparatus are provided for memory device bleeder functionality. For example, some memory cells (e.g., dummy memory cells) within an array of memory cells can be configured as bleeder device, which can be selectively activated to discharge a (e.g., local) sense line to which memory cells of the array are coupled to and/or the memory cells.

### PRIORITY INFORMATION

This application claims the benefit of U.S. Provisional Application No. 63/657,220, filed on Jun. 7, 2024, the contents of which are incorporated herein by reference.

### TECHNICAL FIELD

The present disclosure relates generally to memory apparatuses, and more particularly, to apparatuses and methods for providing memory device bleeder functionality.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, coupled by the access device to a sense line, such as a digit line. The access device can be activated (e.g., to select the cell) by an access line coupled to the access device. The capacitor can store a charge corresponding to a data value of a respective memory cell (e.g., a logic “1” or “0”).

### BRIEF DESCRIPTION OF THE DRAWINGS

FIG. 1 is a schematic illustration of an array of memory cells in a vertical three dimensional (3D) memory in accordance with a number of embodiments of the present disclosure.

FIG. 2 is a perspective view illustrating a portion of horizontal access devices in vertical three dimensional (3D) memory in accordance with a number of embodiments of the present disclosure.

FIGS. 3A and 3B illustrate an example of vertical three dimensional memory including bleeder devices in accordance with a number of embodiments of the present disclosure.

FIGS. 4A and 4B illustrate another example of vertical three dimensional memory including bleeder devices in accordance with a number of embodiments of the present disclosure.

FIG. 5 is a flow diagram corresponding to a method for discharging local sense lines and/or memory cells of an array of memory cells using bleeder devices in accordance with a number of embodiments of the present disclosure.

FIG. 6 is a block diagram of an apparatus in the form of a computing system including a memory device in accordance with a number of embodiments of the present disclosure.

### DETAILED DESCRIPTION

Embodiments of the present disclosure describe apparatuses and methods for providing memory device bleeder functionality. An apparatus can include an array of memory cells, which further includes a local sense line and a plurality of memory cells coupled to the local sense line. One or more memory cells of the plurality of memory cells coupled to the local sense line is configured as a bleeder device to provide a discharge path for the local sense line or remaining memory cells of the plurality of memory cells.

Memory devices can often include bleeder devices in locations to discharge signal lines, transistors (of memory cells), etc. As used herein, the term “bleeder”, “bleeder device” or the like can refer to a device that is configured to provide a (e.g., controlled and safe) discharge path, ensuring that devices and/or circuits are ready for safe operation the next time the devices and/or circuits are accessed. More particularly, bleeder devices can be implemented and activated to discharge local signal lines (e.g., sense lines) of an array of vertically stacked tiers of memory cells when the local signal lines are not selected and/or being accessed.

In some approaches, bleeder devices may be formed as part of circuitry formed adjacent (e.g., under or above) an array of memory cells (e.g., an array of vertically stacked tiers of memory cells). However, the bleeder devices formed on the layer external to the array eventually consume the space of the layer; thereby, imposing restrictions on the overall layer design due to the reduced availability for the other circuits/devices that would have been implemented in the same layer.

Embodiments of the present disclosure are directed to implementing bleeder devices within an array of memory cells. More particularly, embodiments of the present disclosure are directed to utilizing some memory cells (e.g., dummy cells) within the array as bleeder devices. This can be done, for example, by shorting two or more capacitors of respective memory cells to one another, which can form a direct electrical path between transistors of the respective memory cells and a common conductive path (e.g., plate), which eventually serves as the drain (e.g., discharge) path. Therefore, when activated, the transistors can function as bleeder devices to provide a discharge path for the nearby local sense lines and/or the other memory cells (e.g., to ground). The implementation of the bleeder device within the array of memory cells can conserve extra space that might have been occupied by bleeder devices in different approaches. These saved spaces can then be repurposed for integrating other types of devices, such as secondary or additional multiplexer circuitry, for example. This allows for individual and selective access to more sense lines for each unit of the array.

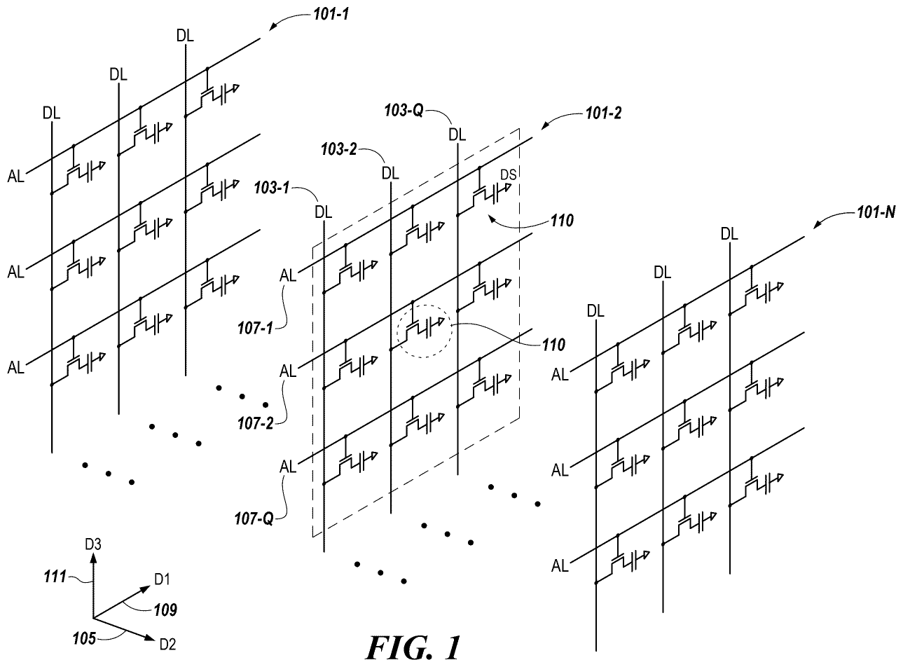

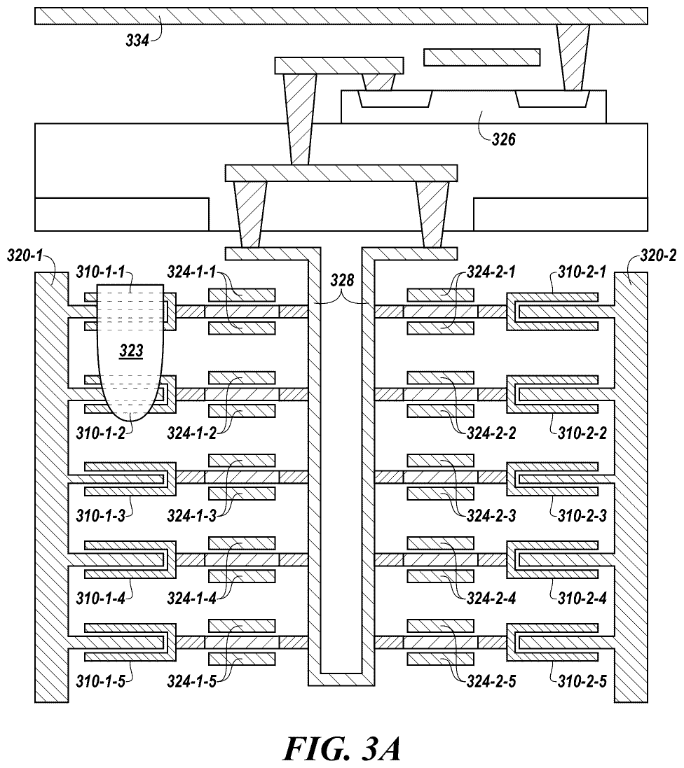

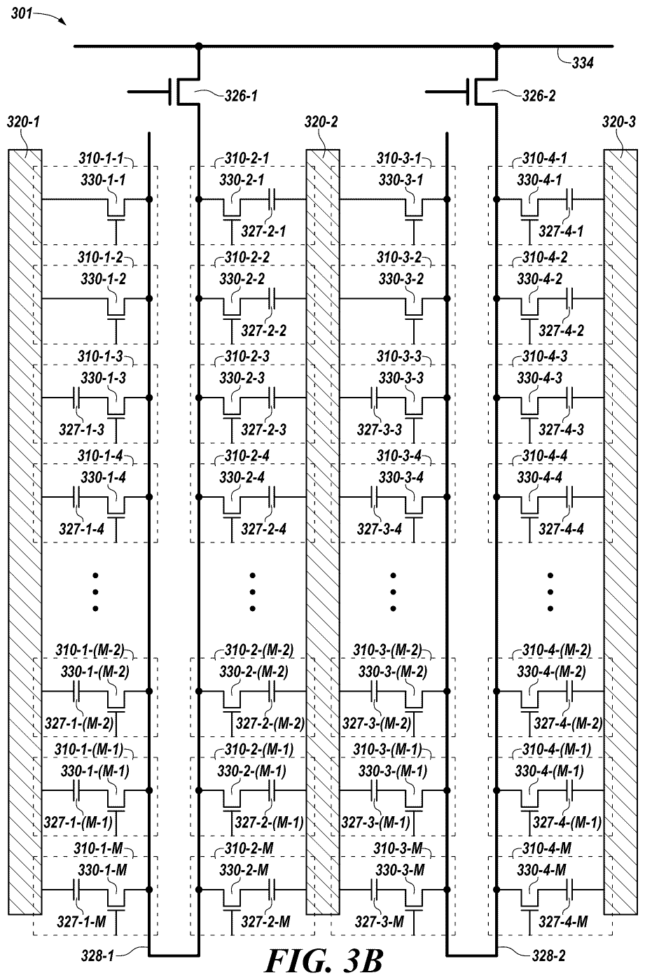

The figures herein follow a numbering convention in which the first digit or digits correspond to the figure number of the drawing and the remaining digits identify an element or component in the drawing. Similar elements or components between different figures may be identified by the use of similar digits. For example, reference numeral 110 may reference element “10” in FIG. 1, and a similar element may be referenced as 310 in FIG. 3. Multiple analogous elements within one figure may be referenced with a reference numeral followed by a hyphen and another numeral or a letter. For example, 107-1 may reference element 107-1 in FIGS. 1 and 107-2 may reference element 107-2, which may be analogous to element 107-1. Such analogous elements may be generally referenced without the hyphen and extra numeral or letter. For example, elements 107-1 and 107-2 or other analogous elements may be generally referenced as 107.

FIG. 1 is a schematic illustration of an array of memory cells in a vertical three dimensional (3D) memory in accordance with a number of embodiments of the present disclosure. FIG. 1 illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to as word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1, the access lines 107-1, 107-2, . . . , 107-Q are illustrated extending in a first direction (D1) 109 and the digit lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., 110, may include an access device, e.g., access transistor, and a storage node, e.g., capacitor, located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . ,107-Q may conductively interconnect memory cells along horizontal rows of each sub cell array 101-1, 101-2, . . . , 101-N, and the digit lines 103-1, 103-2, . . . , 103-Q may conductively interconnect memory cells along vertical columns of each sub cell array 101-1, 101-2, . . . , 101-N. One memory cell, e.g., 110, may be located between one access line, e.g., 107-2, and one digit line, e.g., 103-2. Each memory cell may be uniquely addressed through a combination of an access line 107-1, 107-2, . . . , 107-Q and a digit line 103-1, 103-2, . . . , 103-Q.

The access lines 107-1, 107-2, . . . , 107-P may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., a first source/drain region, of an access device, e.g., transistor, of the memory cell 110 may be connected to a digit line, e.g., 103-2. Each of the memory cells, e.g., memory cell 110, may further include a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

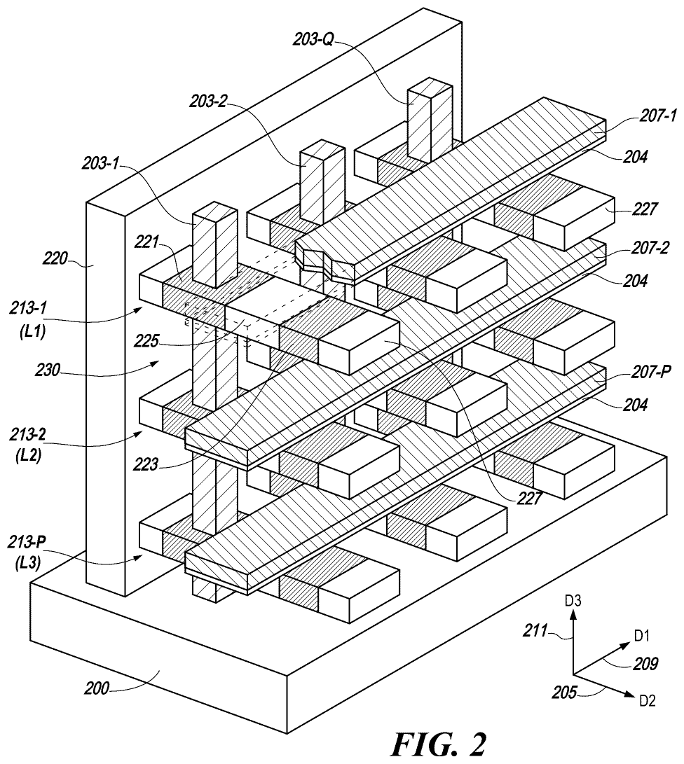

FIG. 2 illustrates a perspective view showing a three dimensional (3D) semiconductor memory device, e.g., a portion of a sub cell array 101-2 shown in FIG. 1 as a vertically oriented stack of memory cells in an array, according to some embodiments of the present disclosure.

As shown in FIG. 2, a substrate 200 may have formed thereon one of the plurality of sub cell arrays, e.g., 101-2, described in connection with FIG. 1. For example, the substrate 200 may be or include a silicon substrate, a germanium substrate, or a silicon-germanium substrate, etc. Embodiments, however, are not limited to these examples.

As shown in the example embodiment of FIG. 2, the substrate 200 may have fabricated thereon a vertically oriented stack of memory cells, e.g., memory cell 110 in FIG. 1, extending in a vertical direction, e.g., third direction (D3) 211. According to some embodiments the vertically oriented stack of memory cells may be fabricated such that each memory cell, e.g., memory cell 110 in FIG. 1, is formed on plurality of vertical levels, e.g., a first level (L1), a second level (L2), and a third level (L3). The repeating, vertical levels, L1, L2, and L3, may be arranged, e.g., “stacked”, a vertical direction, e.g., third direction (D3) 211 shown in FIG. 1, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 207-1, 207-2, . . . , 207-Q connections and digit line 103-1, 103-2, . . . , 103-Q connections. The plurality of discrete components to the horizontally oriented access devices 130, e.g., transistors, may be formed in a plurality of iterations of vertically, repeating layers within each level and may extend horizontally in the second direction (D2) 205, analogous to second direction (D2) 105 shown in FIG. 1.

The plurality of discrete components to the laterally oriented access devices 230, e.g., transistors, may include a first source/drain region 221 and a second source/drain region 223 separated by a channel region 325, extending laterally in the second direction (D2) 205, and formed in a body of the access devices. In some embodiments, the channel region 325 may include silicon, germanium, silicon-germanium, and/or indium gallium zinc oxide (IGZO). In some embodiments, the first and the second source/drain regions, 221 and 223, can include an n-type dopant region formed in a p-type doped body to the access device to form an n-type conductivity transistor. In some embodiments, the first and the second source/drain regions, 221 and 223, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 227, e.g., capacitor, may be connected to one respective end of the access device. As shown in FIG. 2, the storage node 227, e.g., capacitor, may be connected to the second source/drain region 223 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1, may similarly extend in the second direction (D2) 205, analogous to second direction (D2) 205 shown in FIG. 1.

As shown in FIG. 2, a plurality of horizontally oriented access lines 207-1, 207-2, . . . , 207-Q extend in the first direction (D1) 209, analogous to the first direction (D1) 209 in FIG. 1. The plurality of horizontally oriented access lines 207-1, 207-2, . . . , 207-Q may be analogous to the access lines 107-1, 107-2, . . . , 107-Q shown in FIG. 1. The plurality of horizontally oriented access lines 207-1, 207-2, . . . , 207-Q may be arranged, e.g., “stacked”, along the third direction (D3) 211. The plurality of horizontally oriented access lines 207-1, 207-2, . . . , 207-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1) 213-1, (L2) 213-2, and (L3) 213-P, the horizontally oriented memory cells, e.g., memory cell 110 in FIG. 1, may be spaced apart from one another horizontally in the first direction (D1) 209. However, the plurality of discrete components to the horizontally oriented access devices 230, e.g., first source/drain region 221 and second source/drain region 223 separated by a channel region 225, extending laterally in the second direction (D2) 205, and the plurality of horizontally oriented access lines 207-1, 207-2, . . . , 207-Q extending laterally in the first direction (D1) 209, may be formed within different vertical layers within each level. For example, the plurality of horizontally oriented access lines 207-1, 207-2, . . . , 207-Q, extending in the first direction (D1) 209, may be formed on a top surface opposing and electrically coupled to the channel regions 225, separated therefrom by a gate dielectric, and orthogonal to horizontally oriented access devices 230, e.g., transistors, extending in laterally in the second direction (D2) 205. In some embodiments, the plurality of horizontally oriented access lines 207-1, 207-2, . . . , 207-Q, extending in the first direction (D1) 209 are formed in a higher vertical layer, farther from the substrate 200, within a level, e.g., within level (L1), than a layer in which the discrete components, e.g., first source/drain region 221 and second source/drain region 223 separated by a channel region 225, of the horizontally oriented access device are formed.

As shown in the example embodiment of FIG. 2, the digit lines, 203-1, 203-2, . . . , 203-Q, extend in a vertical direction with respect to the substrate 200, e.g., in a third direction (D3) 211. Further, as shown in FIG. 2, the digit lines, 203-1, 203-2, . . . , 203-Q, in one sub cell array, e.g., sub cell array 101-2 in FIG. 1, may be spaced apart from each other in the first direction (D1) 209. The digit lines, 203-1, 203-2, . . . , 203-Q, may be provided, extending vertically relative to the substrate 200 in the third direction (D3) 211 in vertical alignment with source/drain regions to serve as first source/drain regions 221 or, as shown, be vertically adjacent first source/drain regions 221 for each of the horizontally oriented access devices 230, e.g., transistors, extending laterally in the second direction (D2) 205, but adjacent to each other on a level, e.g., first level (L1), in the first direction (D1) 209. Each of the digit lines, 203-1, 203-2, . . . , 203-Q, may vertically extend, in the third direction (D3), on sidewalls adjacent first source/drain regions 221 of respective ones of the plurality of horizontally oriented access devices 230, e.g., transistors, that are vertically stacked. In some embodiments, the plurality of vertically oriented digit lines 203-1, 203-2, . . . , 203-Q, extending in the third direction (D3) 211, may be connected to side surfaces of the first source/drain regions 221 directly and/or through additional contacts including metal silicides.

For example, a first one of the vertically extending digit lines, e.g., 203-1, may be adjacent a sidewall of a first source/drain region 221 to a first one of the horizontally oriented access devices 230, e.g., transistors, in the first level (L1) 213-1, a sidewall of a first source/drain region 221 of a first one of the horizontally oriented access devices 230, e.g., transistors, in the second level (L2) 213-2, and a sidewall of a first source/drain region 221 a first one of the horizontally oriented access devices 230, e.g., transistors, in the third level (L3) 213-P, etc. Similarly, a second one of the vertically extending digit lines, e.g., 203-2, may be adjacent a sidewall to a first source/drain region 221 of a second one of the horizontally oriented access devices 230, e.g., transistors, in the first level (L1) 213-1, spaced apart from the first one of horizontally oriented access devices 230, e.g., transistors, in the first level (L1) 213-1 in the first direction (D1) 209. And the second one of the vertically extending digit lines, e.g., 203-2, may be adjacent a sidewall of a first source/drain region 221 of a second one of the laterally oriented access devices 230, e.g., transistors, in the second level (L2) 213-2, and a sidewall of a first source/drain region 221 of a second one of the horizontally oriented access devices 230, e.g., transistors, in the third level (L3) 213-P, etc. Embodiments are not limited to a particular number of levels.

The vertically extending digit lines, 203-1, 203-2, . . . , 203-Q, may include a conductive material, such as, for example, one of a doped semiconductor material, a conductive metal nitride, metal, and/or a metal-semiconductor compound. The digit lines, 203-1, 203-2, . . . , 203-Q, may correspond to digit lines (DL) described in connection with FIG. 1.

As shown in the example embodiment of FIG. 2, a conductive body contact may be formed extending in the first direction (D1) 209 along an end surface of the horizontally oriented access devices 230, e.g., transistors, in each level (L1) 213-1, (L2) 213-2, and (L3) 213-P above the substrate 100. The body contact 220 may be connected to a body (e.g., body region) of the horizontally oriented access devices 230, e.g., transistors, in each memory cell, e.g., memory cell 110 in FIG. 1. The body contact may include a conductive material such as, for example, one of a doped semiconductor material, a conductive metal nitride, metal, and/or a metal-semiconductor compound.

Although not shown in FIG. 2, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIGS. 3A and 3B illustrate an example vertical three dimensional memory array including bleeder devices (e.g., bleeder devices 310-1-1 and 310-1-2) in accordance with a number of embodiments of the present disclosure. A sub cell array 301 illustrated in FIG. 3A includes a global sense line 334 (alternatively referred to as “global digit line”) that is coupled to one or more local sense line (e.g., local sense line 328 and alternatively referred to as “local digit line”). Although not shown in FIG. 3A, each global sense line (e.g., global sense line 334) can be further coupled to a respective sense amplifier. Although not illustrated in FIG. 3A, a driver (not pictured) can be coupled to the global sense line 334. The driver can be configured to drive current to a local sense line 328 via the global sense line 334 to select a memory cell (e.g., memory cell 310) of a stack of memory cells coupled to the local sense line 328.

In some embodiments, as illustrated in FIG. 3, a global sense line 334 can be coupled to a local sense line 328 via a multiplexor 326. As used herein, the term “multiplexor” refers to circuitry to select one of multiple (e.g., vertical and/or horizontal) sense lines. For example, the local sense line 328 can be selected by activating the multiplexor 326 to electrically coupling the global sense line 334 to the local sense line 328. Alternatively, the multiplexor 326 can be deactivated to decouple the global sense line 334 from the local sense line 328.

Multiplexors (e.g., multiplexor 326) can be located/formed on a layer adjacent to (e.g., under or above) the array of memory cells. Although embodiments are not so limited, the multiplexor 326 can be a complementary metal oxide semiconductor (CMOS) multiplexor and the layer on which the multiplexor 326 is formed can be referred to as CMOS under the array (CuA) circuitry and/or CMOS over the array (CoA).

FIG. 3A also illustrates memory cells 310-1-1, . . . , 310-1-5 (collectively referred to as memory cells 310) coupled to one plate region 320-1 and memory cells 310-2-1, . . . , 310-2-5 (collectively referred to as memory cells 310) coupled to a different plate region 320-2. The plate region can be alternatively referred to as “plate”, “plate conductor”, or the like and can be formed of conductive materials.

More particularly, memory cells 310-1-1, . . . , 310-1-5 are respectively coupled to access lines 324-1-1, . . . , 324-1-5, while memory cells 310-2-1, . . . , 310-2-5 are respectively coupled to access lines 324-2-1, . . . , 324-2-5. Although embodiments are not so limited, access line 324 can be analogous to access lines 103, 203 illustrated in FIGS. 1, 2 and local sense lines 324 can be analogous to sense lines 107, 207 illustrated in FIGS. 1, 2.

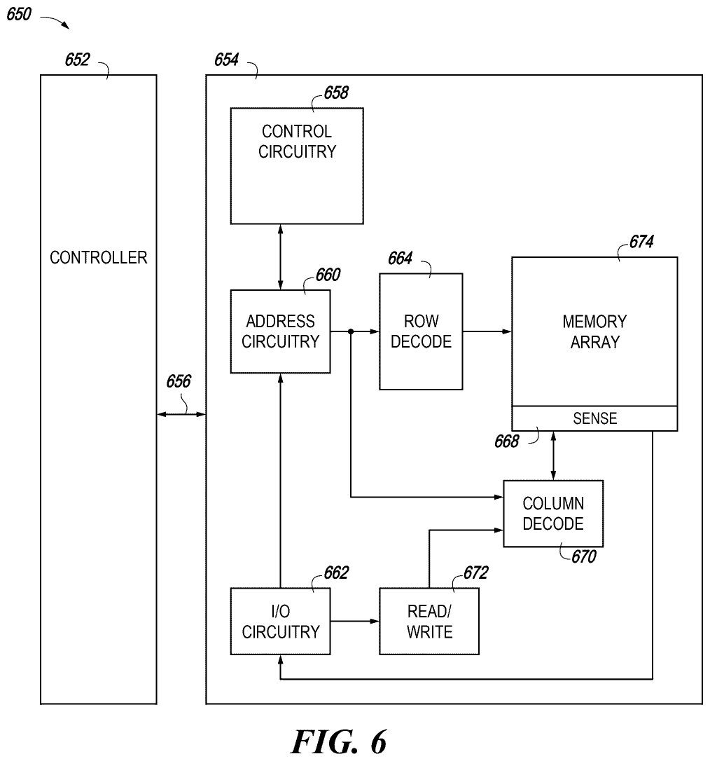

Although not shown in FIGS. 3A-3B, each access line 324 can be coupled to a respective driver (referred to as an access line driver or a word line driver), which can be coupled to a power supply, such as a positive power supply. For example, the control circuitry (e.g., control circuitry 658 illustrated in FIG. 6) can selectively activate one or more access line drivers to provide a positive power supply to the respective access lines 324, which will further provide a differential voltage to the sense amplifier via local sense lines 328.

Although embodiments are not so limited, memory cells 310 illustrated in FIG. 3A can correspond to a particular portion of memory cells, such as storage nodes and/or capacitors. More particularly, each part that is indicated as being “310” in FIG. 3A can correspond to a respective capacitor of each memory cell 310 coated with one or more layers (e.g., oxide layer, conductive layer, etc.).

Those memory cells 310 located on respective layers corresponding to a “dummy” portion 336-1 can be “dummy” memory cells (e.g., cells that are not addressable to store user or host data). For example, memory cells 310-1-1, 310-1-2, 310-2-1, and 310-2-2 located on the “dummy” portion 336-1 can be dummy memory cells, while the other memory cells 310 located on respective layers corresponding to a remaining portion 336-2 can be non-dummy memory cells (e.g., cells that are addressable to store user or host data). Therefore, some of the dummy memory cells of the sub cell array 301 (e.g., dummy memory cells 310-1-1, 310-1-2) are configured as bleeder devices.

FIG. 3B is another illustration of the sub cell array 301. For example, the sub cell array 301 illustrated in FIG. 3B is generally analogous to the sub cell array 301 illustrated in FIG. 3A except that more local sense lines 328 are illustrated and access devices 330 of respective memory cells 310 are further shown. For example, the sub cell array 301 illustrated in FIG. 3A can be analogous to half (e.g., either left or right) of the sub cell array 301 illustrated in FIG. 3B including a respective local sense line 328-1 or 328-2.

For example, memory cells 310-1-1, . . . , 310-1-M (collectively referred to as memory cells 310-1) are coupled between a plate region 320-1 and local sense line 328-1; memory cells 310-2-1, . . . , 310-2-M (collectively referred to as memory cells 310-2) are coupled between a plate region 320-2 and local sense line 328-1; memory cells 310-1-1, . . . , 310-1-M (collectively referred to as memory cells 310-3) are coupled between a plate region 320-2 and local sense line 328-2; and memory cells 310-1-1, . . . , 310-1-M (collectively referred to as memory cells 310-4) are coupled between a plate region 320-3 and local sense line 328-2. As further illustrated in FIG. 3B, memory cells 310 respectively include a transistor 330 and a capacitor 327. For example, memory cells 310-1-3, . . . , 310-1-M can respectively include transistors 330-1-3, . . . , 330-1-M and capacitors 327-1-3, . . . , 327-1-M; memory cells 310-2-3, . . . , 310-2-M can respectively include transistors 330-2-3, . . . , 330-2-M and capacitors 327-2-3, . . . , 327-2-M; memory cells 310-3-3, . . . , 310-3-M can respectively include transistors 330-3-3, . . . , 330-3-M and capacitors 327-3-3, . . . , 327-3-M; and memory cells 310-4-3, . . . , 310-4-M can respectively include transistors 330-4-3, . . . , 330-4-M and capacitors 327-4-3,., 327-4-M.

As further illustrated in FIG. 3B, the sub cell array 301 can further include a dummy layer on another portion (e.g., side) of the sub cell array 301. For example, in addition to those dummy memory cells 310-1-1, 310-1-2, 310-2-1, 310-2-2, 310-3-1, 310-3-2, 310-4-1, 310-4-2 (eventually configured as bleeder devices), the sub cell array 310 can further include dummy memory cells 310-1-(M-1), 310-1-M, 310-2-(M-1), 310-2-M, 310-3-(M-1), 310-3-M, 310-4-(M-1), 310-4-M separated from the dummy memory cells 310-1-1, 310-1-2, 310-2-1, 310-2-2, 310-3-1, 310-3-2, 310-4-1, 310-4-2 by non-dummy memory cells 310.

In embodiments of the present disclosure, some dummy memory cells 310 may be configured as bleeder devices by forming direct electrical (e.g., discharge) paths between transistors 330 of dummy memory cells and plate regions 320. This can be done by creating a space 323 illustrated in FIG. 3A through capacitors of the dummy memory cells (e.g., memory cells 310-1-1, 310-1-2, 310-3-1, 310-3-2 illustrated in FIG. 3B) and filling the space with conductive material to short (e.g., electrically connect or couple) multiple dummy memory cells to one another. Although embodiments are not so limited, the conductive material that can fill the space can include metal materials, such as Copper (Cu), Tungsten (W), Aluminum (Al), etc., polysilicon, epi-silicon, conductive ceramic, or any combination thereof.

For example, as illustrated in FIGS. 3A, two capacitors of dummy memory cells 310-1-1 and 310-1-2 can be shorted to one another. This results in the capacitors of dummy memory cells 310-1-1 and 310-1-2 losing their ability to store charges; thereby, further resulting in access devices (e.g., transistors 330) of the dummy memory cells 310-1-1 and 310-1-2 of FIG. 3A to function as “bleeder transistors”, which provides a controlled discharge path for local sense lines and/or those transistors of memory cells coupled to the local sense lines. For example, as further illustrated in FIG. 3B, the transistors 330-1-1, 330-1-2 (that are directly coupled to the plate region 320-1) of respective dummy memory cells 310-1-1, 310-1-2 can function as bleeder transistors for the local sense line 328-1 and/or those memory cells 310 coupled to the local sense line 328-1, while the transistors 330-3-1, 330-3-2 (that are directly coupled to the plate region 320-2) of respective dummy memory cells 310-3-1, 310-3-2 can function as bleeder transistors for the local sense line 328-2 and/or those memory cells 310 coupled to the local sense line 328-2. Although embodiments are not so limited, transistors 330 (of at least the dummy memory cells 310-1-1, 310-1-2, 310-3-1, 310-3-2) illustrated in FIG. 3B can be a thin film transistor (TFT).

Bleeder transistors 330 can be selectively and individually activated to function as bleeder devices. For example, each transistor 330 can be activated by driving a current to a respective access line 324 by a respective driver (e.g., access line driver). For example, bleeder transistors 330-1-1 and 330-1-2 can be activated when the local sense line 328-1 is not selected (e.g., when the multiplexor 326-1 is deactivated) to discharge the local sense line 328-1 and/or those transistors 330 coupled to the local sense line 328-1. Further, bleeder transistors 330-2-1 and 330-2-2 can be activated when the local sense line 328-2 is not selected (e.g., when the multiplexor 326-2 is deactivated) to discharge the local sense line 328-2 and/or those transistors 330 coupled to the local sense line 328-2.

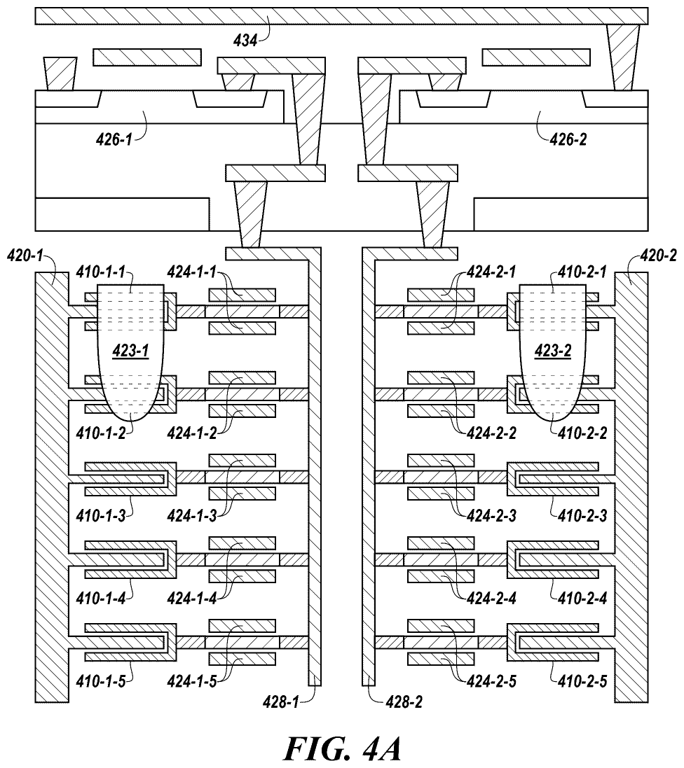

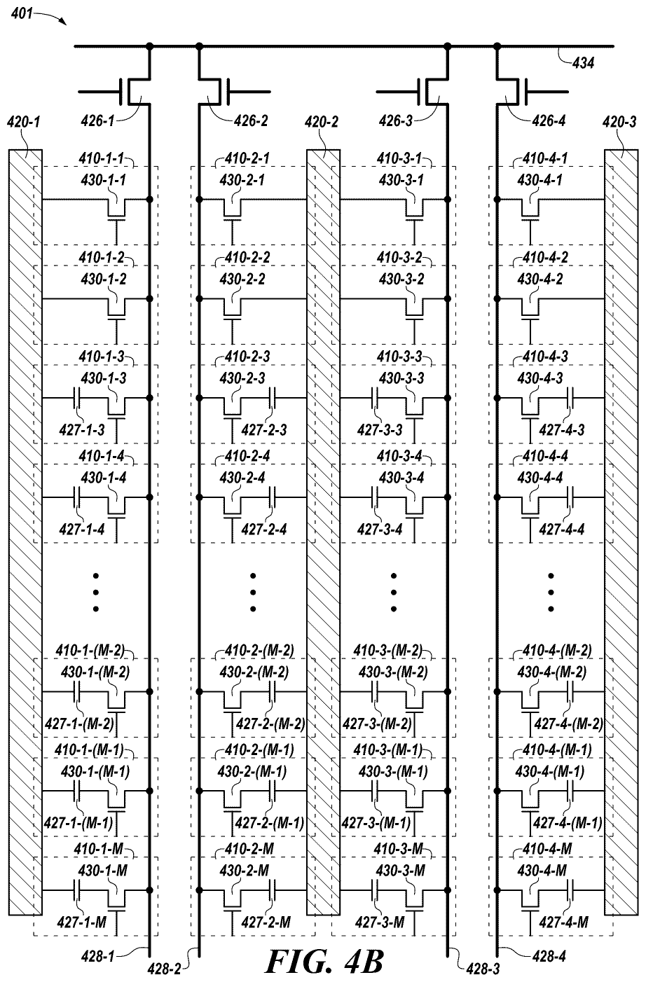

FIGS. 4A and 4B illustrate another example vertical three dimensional memory including bleeder devices (e.g., bleeder devices 410-1-1, 410-1-2, 410-2-1, and 410-2-2) in accordance with a number of embodiments of the present disclosure. The sub cell array 401 illustrated in FIGS. 4A and 4B is generally analogous to the sub cell array 301 illustrated in FIGS. 3A and 3B except that two local sense lines 428-1 and 428-2 respectively corresponding to two plates 420-1 and 420-2 (as compared to the local sense line 328 corresponding to two plates 328) can be individually selected using different multiplexors 426-1 and 426-2. For example, the multiplexor 426-1 can be utilized (e.g., activated) to individually select the local sense line 428-1, while the multiplexor 426-2 can be utilized (e.g., activated) to individually select the local sense line 428-2.

In the example illustrated in FIGS. 4A and 4B, bleeder devices can be implemented on both sides of the sub cell array illustrated in FIG. 4A. For example, memory cells 410-1-1 and 410-1-2 on one side (e.g., coupled to the local sense line 428-1) can be configured as bleeder devices by forming direct electrical (e.g., discharge) paths between transistors 430-1-1 and 430-1-2 and the plate 420-1. Further, for example, memory cells 410-2-1 and 410-2-2 on another side (e.g., coupled to the local sense line 428-2) can be configured as bleeder devices by forming direct electrical paths between transistors 430-2-1 and 430-2-2 and plate 420-1.

More particularly, bleeder transistors 430-1-1 and 430-1-2 can be activated when the local sense line 428-1 is not selected (e.g., when the multiplexor 426-1 is deactivated) to discharge the local sense line 428-1 and/or those transistors 430 coupled to the local sense line 428-1; bleeder transistors 430-2-1 and 430-2-2 can be activated when the local sense line 428-2 is not selected (e.g., when the multiplexor 426-2 is deactivated) to discharge the local sense line 428-2 and/or those transistors 430 coupled to the local sense line 428-2; bleeder transistors 430-3-1 and 430-3-2 can be activated when the local sense line 428-3 is not selected (e.g., when the multiplexor 426-3 is deactivated) to discharge the local sense line 428-3 and/or those transistors 430 coupled to the local sense line 428-3; and bleeder transistors 430-4-1 and 430-4-2 can be activated when the local sense line 428-4 is not selected (e.g., when the multiplexor 426-4 is deactivated) to discharge the local sense line 428-4 and/or those transistors 430 coupled to the local sense line 428-4.

Since bleeder device are formed within the array of memory cells by configuring dummy memory cells as bleeder devices, a space that would have been otherwise utilized as a bleeder device can now be utilized for forming a secondary multiplexor (e.g., the multiplexor 426-1 in addition to the multiplexor 426-2) to selectively control two separate local sense lines 428-1 and 428-2. The layer 422 in which the multiplexors 426 are formed offers more space than the space that would have been offered for multiplexors when formed within the array of memory cells. This allows multiplexors 426 to be “strong” multiplexors, such as CMOS multiplexors, which typically occupy more space than the other multiplexors, such as NMOS multiplexors. For example, although CMOS multiplexors may occupy more space than NMOS multiplexors, CMOS multiplexors can provide better performance/reliability as compared to NMOS multiplexors in terms of speed and current-carrying capacity, etc. For example, CMOS multiplexors can offer advantages over NMOS multiplexors, attributed to the swift low-to-high and high-to-low output transitions facilitated by the low resistance pull-up transistors inherent in CMOS architecture.

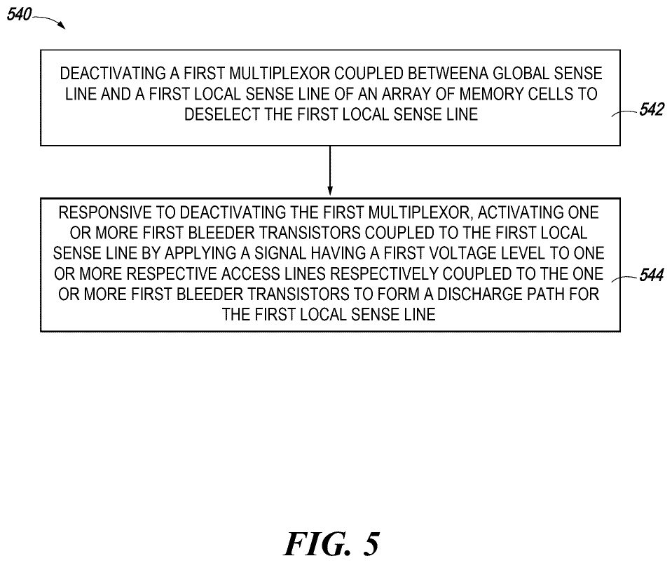

FIG. 5 is a flow diagram corresponding to a method 540 for discharging local sense lines and/or memory cells of an array of memory cells using bleeder devices in accordance with a number of embodiments of the present disclosure. The method 540 can be performed by processing logic (e.g., the control logic 658 illustrated in FIG. 6) that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 542, the method 540 can include deactivating a first multiplexor (e.g., the multiplexor 326-1, 426-1, 426-3 illustrated in FIGS. 3A, 3B, 4A, 4B) coupled between a global sense line (e.g., the global sense line 334, 434 illustrated in FIGS. 3A, 3B, 4A, 4B) and a first local sense line (e.g., the local sense line 328-1, 428-1, 428-3 illustrated in FIGS. 3A, 3B, 4A, 4B) of an array of memory cells (e.g., the array of memory cells 674) to deselect the first local sense line 328-1, 428-1, 428-3. At block 544, the method 540 can include activating one or more first bleeder transistors line (e.g., the bleeder transistors 330-1-1, 330-1-2, 430-1-1, 430-1-2, 430-3-1, 430-3-2 illustrated in FIGS. 3A, 3B, 4A, 4B) coupled to the first local sense line 328-1, 428-1, 428-3 to form a discharge path for the first local sense line 328-1, 428-1, 428-3. The one or more first bleeder transistors 330-1-1, 330-1-2, 430-1-1, 430-1-2, 430-3-1, 430-3-2 can be activated responsive to deactivating the first multiplexor 326-1, 426-1, 426-3 and by applying a signal having a first voltage level to one or more respective access lines (e.g., the access lines 324, 424 illustrated in FIGS. 3A, 3B, 4A, 4B) respectively coupled to the one or more first bleeder transistors 330-1-1, 330-1-2, 430-1-1, 430-1-2, 430-3-1, 430-3-2. The first voltage level can be a voltage level corresponding to a ground voltage, Vss, or a voltage level lower than that of the threshold voltage of the bleeder transistors 330-1-1, 330-1-2, 430-1-1, 430-1-2, 430-3-1, 430-3-2.

Alternatively, the one or more first bleeder transistors 330-1-1, 330-1-2, 430-1-1, 430-1-2, 430-3-1, 430-3-2 can be deactivated (responsive to activating the first multiplexor 326-1, 426-1, 426-3 to select the first local sense line) to block the discharge path for the first local sense line 328-1, 428-1, 428-3. The one or more first bleeder transistors 330-1-1, 330-1-2, 430-1-1, 430-1-2, 430-3-1, 430-3-2 can be deactivated by applying a signal having a second voltage level to the one or more respective access lines 324, 424 respectively coupled to the one or more first bleeder transistors 330-1-1, 330-1-2, 430-1-1, 430-1-2, 430-3-1, 430-3-2. The second voltage level can be higher than that of the threshold voltage of the bleeder transistors 330-1-1, 330-1-2, 430-1-1, 430-1-2, 430-3-1, 430-3-2 and/or a voltage level corresponding to (or higher than) a power supply voltage, Vdd.

In some embodiments, the array of memory cells further includes a second local sense line (e.g., the local sense line 328-2, 428-2, 428-4 illustrated in FIGS. 3A, 3B, 4A, 4B) that is coupled to the global sense line via a second multiplexor (e.g., the multiplexor 326-2, 426-2, 426-4 illustrated in FIGS. 3A, 3B, 4A, 4B). In this example, the method 540 can further include deactivating the second multiplexor 326-2, 426-2, 426-4 to deselect the second local sense line 328- 2, 428-2, 428-4. Further, the method 540 can include activating one or more second bleeder transistors (e.g., the bleeder transistors 330-3-1, 330-3-2, 430-2-1, 430-2-2, 430-4-1, 430-4-2 illustrated in FIGS. 3A, 3B, 4A, 4B) coupled to the second local sense line 328-2, 428-2, 428-4 can be activated (responsive to deactivating the second multiplexor 326-2, 426-2, 426-4) to form a discharge path for the second local sense line 328-2, 428-2, 428-4. The one or more second bleeder transistors 330-3-1, 330-3-2, 430-2-1, 430-2-2, 430-4-1, 430-4-2 can be activated by applying a signal having a third voltage level to one or more respective access lines (e.g., the access lines 324, 424 illustrated in FIGS. 3A, 3B, 4A, 4B) respectively coupled to the one or more second bleeder transistors 330-3-1, 330-3-2, 430-2-1, 430-2-2, 430-4-1, 430-4-2. The third voltage level can correspond to the first voltage level. For example, the third voltage level can be a voltage level corresponding to a ground voltage, Vss, or a voltage level lower than that of the threshold voltage of the bleeder transistors 330-3-1, 330-3-2, 430-2-1, 430-2-2, 430-4-1, 430-4-2.

Continuing with the example above, the method 540 can include activating the second multiplexor 326-2, 426-2, 426-4 to select the second local sense line 328-2, 428-2, 428-4. In this example, the one or more second bleeder transistors 330-3-1, 330-3-2, 430-2-1, 430-2-2, 430-4-1, 430-4-2 can be deactivated (responsive to activating the second multiplexor 326-2, 426-2, 426-4) to block the discharge path for the second local sense line 328-2, 428-2, 428-4. The one or more second bleeder transistors 330-3-1, 330-3-2, 430-2-1, 430-2-2, 430-4-1, 430-4-2 can be deactivated by applying a signal having a fourth voltage level lower than the third voltage level to the one or more respective access lines 324, 424 respectively coupled to the one or more second bleeder transistors 330-3-1, 330-3-2, 430-2-1, 430-2-2, 430-4-1, 430-4-2. The fourth voltage level can correspond to the second voltage level. For example the fourth voltage level can be higher than that of the threshold voltage of the bleeder transistors 330-3-1, 330-3-2, 430-2-1, 430-2-2, 430-4-1, 430-4-2 and/or a voltage level corresponding to (or higher than) a power supply voltage, Vdd.

FIG. 6 is a block diagram of an apparatus in the form of a computing system 650 including a memory device 654 in accordance with a number of embodiments of the present disclosure. As used herein, a memory device 654, a memory array 674, and/or a host 652, for example, might also be separately considered an “apparatus.” According to embodiments, the memory device 654 may comprise at least one memory array 674 with a memory cell formed having a digit line and body contact, according to the embodiments described herein.

In this example, system 650 includes a host 652 coupled to memory device 654 via an interface 656. The computing system 650 can be a personal laptop computer, a desktop computer, a digital camera, a mobile telephone, a memory card reader, or an Internet-of-Things (IoT) enabled device, among various other types of systems. Host 652 can include a number of processing resources (e.g., one or more processors, microprocessors, or some other type of controlling circuitry) capable of accessing memory 654. The system 650 can include separate integrated circuits, or both the host 652 and the memory device 654 can be on the same integrated circuit. For example, the host 652 may be a system controller of a memory system comprising multiple memory devices 654, with the system controller 652 providing access to the respective memory devices 654 by another processing resource such as a central processing unit (CPU).

In the example shown in FIG. 6, the host 652 is responsible for executing an operating system (OS) and/or various applications (e.g., processes) that can be loaded thereto (e.g., from memory device 654 via control circuitry 658). The OS and/or various applications can be loaded from the memory device 654 by providing access commands from the host 652 to the memory device 654 to access the data comprising the OS and/or the various applications. The host 652 can also access data utilized by the OS and/or various applications by providing access commands to the memory device 654 to retrieve said data utilized in the execution of the OS and/or the various applications.

For clarity, the system 650 has been simplified to focus on features with particular relevance to the present disclosure. The memory array 674 can be a DRAM array comprising at least one memory cell having a digit line and body contact formed according to the techniques described herein. For example, the memory array 674 can be an unshielded DL 4F2 array such as a 3D-DRAM memory array. The array 674 can comprise memory cells arranged in rows coupled by word lines (which may be referred to herein as access lines or select lines) and columns coupled by digit lines (which may be referred to herein as sense lines or data lines). Although a single array 674 is shown in FIG. 6, embodiments are not so limited. For instance, memory device 654 may include a number of arrays 674 (e.g., a number of banks of DRAM cells).

The memory device 654 includes address circuitry 660 to latch address signals provided over an interface 656. The interface can include, for example, a physical interface employing a suitable protocol (e.g., a data bus, an address bus, and a command bus, or a combined data/address/command bus). Such protocol may be custom or proprietary, or the interface 656 may employ a standardized protocol, such as Peripheral Component Interconnect Express (PCIe), Gen-Z, CCIX, or the like. Address signals are received and decoded by a row decoder 664 and a column decoder 670 to access the memory array 674. Data can be read from memory array 674 by sensing voltage and/or current changes on the sense lines using sensing circuitry 668. The sensing circuitry 668 can comprise, for example, sense amplifiers that can read and latch a page (e.g., row) of data from the memory array 674. The I/O circuitry 662 can be used for bi-directional data communication with the host 652 over the interface 656. The read/write circuitry 672 is used to write data to the memory array 674 or read data from the memory array 674. As an example, the circuitry 672 can comprise various drivers, latch circuitry, etc.

Control circuitry 658 decodes signals provided by the host 652. The signals can be commands provided by the host 652. These signals can include chip enable signals, write enable signals, and address latch signals that are used to control operations performed on the memory array 674, including data read operations, data write operations, and data erase operations. In various embodiments, the control circuitry 658 is responsible for executing instructions from the host 652. The control circuitry 658 can comprise a state machine, a sequencer, and/or some other type of control circuitry, which may be implemented in the form of hardware, firmware, or software, or any combination of the three. In some examples, the host 652 can be a controller external to the memory device 654. For example, the host 652 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. An apparatus, comprising:
an array of memory cells comprising:
a local sense line; and
a plurality of memory cells coupled to the local sense line, wherein one or more memory cells of the plurality of memory cells coupled to the local sense line is configured as a bleeder device to provide a discharge path for the local sense line or remaining memory cells of the plurality of memory cells.

2. The apparatus of claim 1, wherein:
the plurality of memory cells are coupled between the local sense line and a plate conductor; and
respective access devices of memory cells corresponding to the one or more memory cells of the plurality of memory cells configured as the bleeder device is directly coupled to the plate conductor.

3. The apparatus of claim 2, wherein:
respective capacitors of the memory cells corresponding to the one or more memory cells of the plurality of memory cells are coupled between the respective access devices and the plate conductor; and
wherein the respective capacitors are shorted to one another to form a direct path between the respective access devices and the plate conductor.

4. The apparatus of claim 2, wherein one or more memory cells corresponding to the one or more memory cells of the plurality of memory cells correspond to dummy memory cells.

5. The apparatus of claim 1, wherein one or more memory cells corresponding to the one or more memory cells of the plurality of memory cells are respectively coupled to one or more access lines.

6. The apparatus of claim 5, wherein the one or more access lines are further coupled to additional memory cells.

7. The apparatus of claim 1, further comprising:
a layer located adjacent to the array of memory cells and in which one or more multiplexors are formed; and
a global sense line coupled to the local sense line via the one or more multiplexors.

8. An apparatus, comprising:
a global sense line; and
an array of memory cells, comprising:
a first local sense line coupled to the global sense line via one or more multiplexors;
a first plurality of memory cells coupled to the first local sense line and respectively to a plurality of access lines; and
one or more bleeder transistors coupled to the first local sense line and respectively to one or more access lines.

9. The apparatus of claim 8, wherein:
a first portion of the first plurality of memory cells is coupled between the first local sense line and a first plate conductor; and
a second portion of the first plurality of memory cells is coupled between the first local sense line and a second plate conductor.

10. The apparatus of claim 9, wherein:
a first bleeder transistor of the one or more bleeder transistors is coupled to the first plate conductor; and
a second bleeder transistor of the one or more bleeder transistors is coupled to the second plate conductor.

11. The apparatus of claim 8, wherein:
the first local sense line is coupled to the global sense line via a first multiplexor; and
the array of memory cells further comprises a second plurality of memory cells coupled to a second local sense line and respectively to a plurality of access lines, wherein the second local sense line is coupled to the global sense line via a second multiplexor.

12. The apparatus of claim 8, further comprising a layer adjacent to the array of memory cells, in which the first and second multiplexors are formed.

13. The apparatus of claim 8, wherein: each access line of the one or more access lines coupled to the one or more bleeder transistors is further coupled to one or more memory cells of the array of memory cells.

14. The apparatus of claim 8, wherein at least one of the one or more multiplexors is a complementary metal oxide semiconductor (CMOS) transistor.

15. The apparatus of claim 8, wherein at least one of the one or more bleeder transistors is a thin-film-transistor (TFT).

16. A method, comprising:
deactivating a first multiplexor coupled between a global sense line and a first local sense line of an array of memory cells to deselect the first local sense line; and
responsive to deactivating the first multiplexor, activating one or more first bleeder transistors coupled to the first local sense line by applying a signal having a first voltage level to one or more respective access lines respectively coupled to the one or more first bleeder transistors to form a discharge path for the first local sense line.

17. The method of claim 16, further comprising:
activating the first multiplexor to select the first local sense line; and
responsive to activating the first multiplexor, deactivating the one or more first bleeder transistors by applying a signal having a second voltage level lower than the first voltage level to the one or more respective access lines respectively coupled to the one or more first bleeder transistors to block the discharge path for the first local sense line.

18. The method of claim 16, wherein the array of memory cells further comprises a second local sense line that is coupled to the global sense line via a second multiplexor.

19. The method of claim 18, further comprising:
deactivating the second multiplexor to deselect the second local sense line; and
responsive to deactivating the second multiplexor, activating one or more second bleeder transistors coupled to the second local sense line by applying a signal having a third voltage level to one or more respective access lines respectively coupled to the one or more second bleeder transistors to form a discharge path for the second local sense line.

20. The method of claim 19, further comprising:
activating the second multiplexor to select the second local sense line; and
responsive to activating the second multiplexor, deactivating the one or more second bleeder transistors by applying a signal having a fourth voltage level lower than the third voltage level to the one or more respective access lines respectively coupled to the one or more second bleeder transistors to block the discharge path for the second local sense line.
